(19) United States
(12) Patent Application Publication
(10) Pub. No.: US 2003/0090274 A1
(43) Pub. Date: May 15, 2003

(54) Laser-trimming fuse detecting circuit and method for semiconductor integrated circuit

(75) Inventor: Osamu Kitade, Tokyo (JP)

Correspondence Address: MCDERMOTT, WILL & EMERY, 600 13th Street, N.W., Washington, DC, 20005-3096, US

(73) Assignee: Mitsubishi Denki Kabushiki Kaisha

(21) Appl. No.: 10/135,508

(22) Filed: May 1, 2002

(30) Foreign Application Priority Data
Nov. 15, 2001 (JP) 2001-350033

(51) Int. Cl. G01R 31/02; H01H 85/30

(52) U.S. Cl. 324/550

(57) ABSTRACT

In a laser-trimming fuse detecting circuit, a laser-trimming fuse circuit 1 includes a laser trimming fuse 2, and a node 4 has a predetermined potential difference from a external pad 3, and a laser-trimming fuse detecting circuit 5 is connected between the laser-trimming fuse circuit 1 and the external pad 3, and the laser-trimming fuse detecting circuit 5 has switching means to be turned on/off in accordance with input of a test mode signal (TE).

### BACKGROUND OF THE INVENTION

1. Field of the Invention

The present invention generally relates to a semiconductor integrated circuit, and particularly to a laser-trimming fuse detecting circuit and method for detecting presence or absence of an uncut fuse portion and determining success or failure of a fuse cut state.

2. Description of the Prior Art

When a circuit element is damaged due to a defect produced in a semiconductor-device fabricating process, the damaged circuit element is remedied by a redundant (or spare) circuit previously mounted on a semiconductor chip. A typical example of such a redundant circuit is adapted to replace a defective memory cell of a semiconductor memory by a normal one. Regarding a semiconductor memory, most defects caused in a manufacturing process are produced in a memory-cell section. By remedying the defects in the memory-cell section, it is possible to greatly improve the yield. A redundant memory cell replaces and remedies an independent memory-cell defect, a linear word-line defect (X-line defect), and a bit-line defect (Y-line defect) one by one word or bit line under the control of a redundant circuit.

For example, when a defective word line is to be remedied by replacing it with a redundant word line, the defective word line is separated from a normal memory cell array by cutting a fuse provided in a driver circuit allocated to the defective word line. Outputs of the driver circuit are always fixed to a non-selection (disable) level after cutting the fuse and the defective word line is in an inoperable condition.

Then, in order to replace the defective word line with a redundant word line, address information corresponding to the defective word line is programmed to a fuse in a redundant word line control circuit to select a redundant line instead of the defective line. In this case, a row decoder is used to constitute a redundant circuit for every word line. The same operation as above is performed by using a column decoder in the case of constituting a redundant circuit for replacement of bit lines. Most semiconductor memories have redundant-circuit functions both in word lines and bit lines.

In this technique, a fuse cutting operation is performed generally using a laser trimmer for blowing the fuse with a laser beam in accordance with information on the result of executing a wafer-testing step.

When blowing a fuse with a laser beam by using a laser trimmer, there are used a method of optimizing energy quantity of a laser beam and a method of controlling a shift from a laser-beam-applying direction for accurately focusing the laser beam to an aimed part. However, in a mass-production process, there may occur imperfect cutting of a fuse, that is, a state in which a slight uncut portion is left.

Thus, when a fuse is not accurately blown due to a fuse-blow error or the like in a laser trimming (hereafter referred to as LT) process and imperfect cutting such as an uncut fuse occurs, there arises a problem that a slight leak current flows through a program circuit for switching with redundancy and that a trouble such as multi-selection or a circuit malfunctions occurs after a fuse test.

### SUMMARY OF THE INVENTION

The present invention has been developed to solve these problems and has an object to provide an LT fuse detecting circuit for detecting whether a fuse is accurately blown before executing actual full-scale LT process in a semiconductor integrated circuit.

Another object of the present invention is to provide an LT fuse detecting circuit for determining whether a fuse is accurately blown after executing the actual full-scale LT process in a semiconductor integrated circuit.

Further another object of the present invention is to provide a method for determining success or failure of a LT-fuse blow state.

In order to achieve the above objects, a first aspect of the present invention provides a laser-trimming fuse detecting circuit for determining a blown state of a laser-trimming fuse of a semiconductor integrated circuit, which includes: a laser-trimming fuse circuit provided in a chip section of the semiconductor integrated circuit and having a laser trimming fuse; an external pad; and a node having a predetermined potential difference from the external pad. In this arrangement, the external pad is connected with the node in series through the laser-trimming fuse to determine a blown state of the laser-trimming fuse by the external pad.

In the above configuration, the laser trimming fuse of the laser-trimming fuse circuit may be preliminarily blown before executing a full-scale laser trimming process.

Moreover, in the above configuration, a laser-trimming fuse detecting circuit may be further connected between the laser-trimming fuse circuit and the external pad, where the laser-trimming fuse detecting circuit has switching means to be turned on/off in accordance with input of a test mode signal, so that the laser-trimming fuse circuit is electrically connected with the external pad when the switching means is turned on.

Furthermore, in the above configuration, the laser-trimming fuse circuit may be located in a TEG section of the semiconductor integrated circuit.

A second aspect of the present invention provides a laser-trimming fuse detecting circuit for determining a blown state of a laser trimming fuse of a semiconductor integrated circuit, which includes: a spare circuit; an external pad; and a laser-trimming fuse detecting circuit connected between the spare circuit and the external pad.

In this arrangement, the laser-trimming fuse detecting circuit is provided with a plurality of switching elements which are connected in parallel with each other, and the spare circuit is provided with a plurality of laser trimming fuses which are connected in parallel with each other correspondingly to the switching elements, respectively, and each of the switching elements is connected between the corresponding laser trimming fuse and the external pad.

In this arrangement, each of the switching elements is turned on/off in accordance with input of a test mode signal.

In the configuration of the second aspect, the spare circuit may include a plurality of second switching elements between the laser trimming fuses and a ground, and each of the second switching elements receives an input address signal Xi as a gate signal thereof.

Moreover, in the configuration of the second aspect, a laser-trimming fuse detecting mode may be started after executing a laser trimming process and a fuse actually blown is subject to blow-check in the laser-trimming fuse detecting model and when it is judged that the blow-checked fuse is not accurately blown, an overvoltage is applied to the spare circuit from the external pad to thereby perfectly blow the fuse again.

A third aspect of the present invention provides a laser-trimming fuse detecting circuit for determining a blown state of a laser trimming fuse of a semiconductor integrated circuit, which includes: a first laser-trimming fuse detecting circuit in which a fuse is connected between a node and a ground in series; a second laser-trimming fuse detecting circuit having a switching element and a first logic circuit; and an internal-clock generating circuit which includes a second logic circuit. One input terminal of the second logic circuit receives an output of the second laser-trimming fuse detecting circuit to generate an internal operation clock. Thus, a blown state of a laser-trimming fuse is detected with an internal operation of the internal-clock generating circuit kept disable.

In this configuration, the first laser-trimming fuse detecting circuit may include a plurality of fuses arranged in parallel.

A fourth aspect of the present invention provides a laser-trimming fuse detecting method for determining a blown state of a laser trimming fuse in a laser trimming process of a semiconductor integrated circuit, which includes steps of: blow-cutting a laser trimming fuse connected between an external pad and a node of a chip section of the semiconductor integrated circuit; applying a predetermined potential difference between the external pad and the node; and monitoring a current flowing through the external pad. In this method, a blown state of the laser-trimming fuse is determined by the external pad.

In the method of the fourth aspect, the laser trimming fuse may be preliminarily blown before executing a full-scale laser trimming process.

Moreover, in this method, the laser trimming process may include steps of: starting a test mode for detecting an laser-trimming fuse; electrically connecting the laser trimming fuse with the external pad; and determining success or failure of the fuse blow state by monitoring a current flowing through the external pad.

A fifth aspect of the present invention provides a laser-trimming fuse detecting method for determining a blown state of a laser-trimming fuse of a spare circuit from an external pad in a semiconductor integrated circuit, which includes: blow-cutting a laser-trimming fuse corresponding to a defective address among input addresses; starting a test mode for detecting a blown state of a laser-trimming fuse in a laser trimming process; and electrically connecting the external pad with the node; and determining a blown state of the laser-trimming fuse through the external pad by monitoring the current flowing through the external pad.

In this method, the test mode may be started after executing a laser trimming process and a fuse actually blown is subject to blow-check in the test mode, and when it is judged that the blow-checked fuse is not accurately blown, an overvoltage is applied to the spare circuit from the external pad to thereby perfectly blow the fuse again.

According to the present invention, it becomes possible to previously confirm whether energy quantity for fuse blowing is normal in a LT process. If the energy quantity is abnormal, it is possible to optimize the energy quantity for the fuse blow before executing a fuse blow in a full-scale LT process to thereby prevent a blow error.

Moreover, it is possible to efficiently determine the quality for the fuse blow according to necessity by providing a step of starting a test mode before or after a LT process.

Furthermore, advantages are obtained that a fuse actually blown can be subject to blow-check and if the fuse is not accurately blown, the fuse can be accurately blown by blowing the fuse again or blowing the fuse again by changing energy quantities for the fuse blow.

### BRIEF DESCRIPTION OF THE DRAWINGS

These and other objects and features of the present invention will be readily understood from the following detailed description taken in conjunction with preferred embodiments thereof with reference to the accompanying drawings, in which like parts are designated by like reference numerals and in which:.

FIG. 1 is a circuit diagram of a LT-fuse detecting circuit according to first and third embodiments of the present invention;

FIGS. 2A to 2C are schematic sectional views showing cut states of a fuse in an LT-fuse detecting circuit according to the present invention;

FIG. 3 is an illustration for explaining the determination on the cut state of the fuse shown in FIG. 2;

FIG. 4 is a circuit diagram of a LT-fuse detecting circuit according to a second embodiment of the present invention;

FIG. 5 is a circuit diagram of a LT-fuse detecting circuit according to fourth and fifth embodiments of the present invention;

FIG. 6 is a circuit diagram of a LT-fuse detecting circuit according to sixth embodiment of the present invention; and

FIG. 7 is a circuit diagram of a LT-fuse detecting circuit according to a seventh embodiment of the present invention.

### DETAILED DESCRIPTION OF THE PREFERRED EMBODIMENTS

Before the description proceeds, it is to be noted that, since the basic structures of the preferred embodiments are in common, like parts are designated by the same reference numerals throughout the accompanying drawings.

[Embodiment 1]

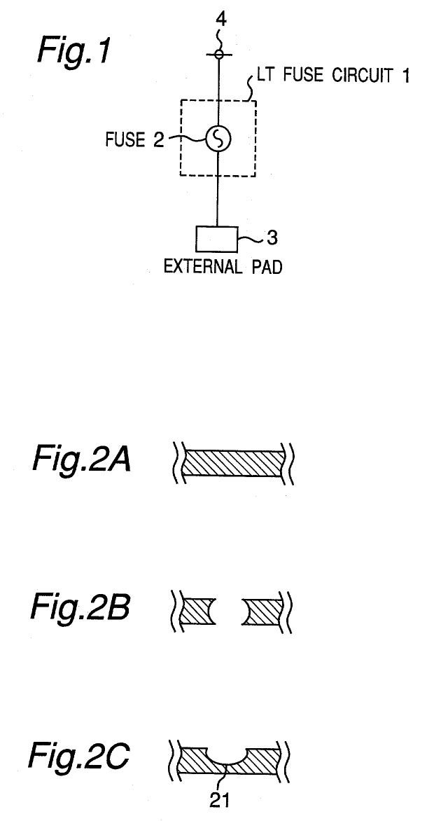

FIG. 1 is a circuit diagram showing the first embodiment of an LT-fuse detecting circuit according to the present invention.

In this embodiment, an LT-fuse circuit 1 having an LT-test fuse 2 is electrically connected between an external pad 3 and a node 4 in a semiconductor integrated circuit chip as shown in FIG. 1. By this arrangement, optimization is previously confirmed with regard to LT-fuse-blow setting conditions such as a laser-beam energy quantity and a laser-beam applying direction in executing a LT-fuse blow.

That is, the LT-test fuse 2 in the LT-fuse circuit 1 is preliminarily blown by a laser beam emitted from a laser trimmer (not illustrated) at the start of a LT process. In this operation, a predetermined potential difference is applied between the external pad 3 and the node 4 to confirm whether the fuse 2 is accurately blown by monitoring a voltage or current by the external pad 3 (which is referred to as “previous LT check”). When it is judged that the fuse 2 is accurately blown, it is determined that the LT-fuse-blow setting conditions are good, and then an actual fuse such as a Row (row-directional) fuse, a Col (column-directional) fuse, and an internal-power-source fuse are blown (which is referred to as “full-scale LT”)

FIGS. 2A to 2C are illustrations showing results of the fuse 2 subjected to LT-blowing by a laser beam, in which FIG. 2A illustrates an uncut LT fuse, FIG. 2B illustrates a perfectly-cut LT fuse, and FIG. 2C illustrates an imperfectly-cut fuse. As shown in FIG. 2B, when the fuse is perfectly cut, the external pad 3 is electrically disconnected from the node 4 as shown in FIG. 1, and then no current flows through the circuit between the external pad 3 and the node 4. However, when the fuse is imperfectly cut as shown in FIG. 2C, the potential between the external pad 3 and the node 4 is varied because the external pad 3 is electrically connected with the node 4 by an uncut connective portion 21.

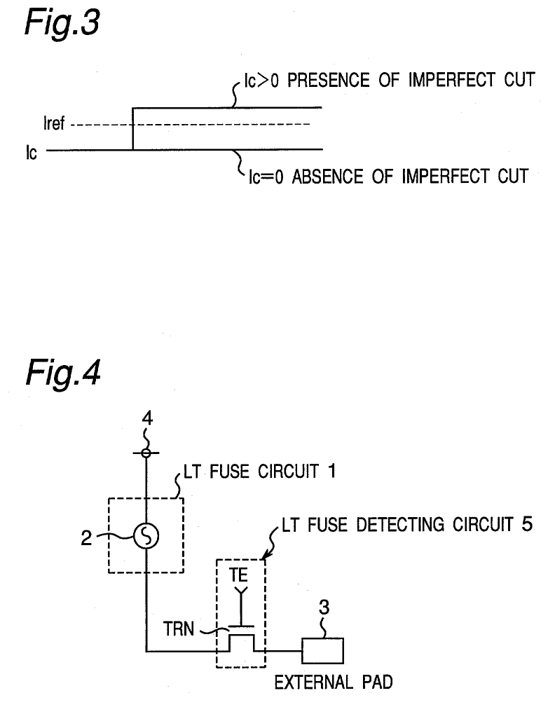

That is, as shown in FIG. 3, a current Ic flows between the external pad 3 of a potential Vpad and the node 4 of a potential Vss. Therefore, by monitoring the current Ic by the external pad 3, it is possible to determine presence or absence of an imperfectly-cut fuse.

In FIG. 3, it is possible to determine that a cut state of the fuse is perfect when the current Ic is equal to 0 and a cut state of the fuse is imperfect when the current Ic is larger than 0. Alternatively, when considering that the current Ic is kept in a very small range in which the current Ic does not influence the circuit operations, it may be possible to judge the success or failure of the fuse cut state by previously setting a threshold Iref which is set as a value of, for example, ⅓ of the current Imax when the fuse is not cut at all as shown in FIG. 2A. In this case, when a current exceeds the threshold Iref, it is determined that a fuse is imperfectly cut.

When it is determined in the previous check for fuse-cut state determination that a fuse is imperfectly cut, an action such as optimization of the energy quantity of a laser beam or re-control of the shift of a laser-beam applying direction is taken so that an LT fuse is perfectly cut in a full-scale LT process.

Accordingly, the first embodiment of the present invention has advantages that it is possible to previously confirm whether the energy quantity for the fuse blow is normal, and if it is abnormal, optimization of the energy quantity for the fuse blow is performed before blowing a fuse in full-scale LT, thus preventing a blow error.

[Embodiment 2]

FIG. 4 is a circuit diagram showing a second embodiment of the present invention. As shown in FIG. 4, in this embodiment, an LT-fuse detecting circuit 5 is further connected between the LT fuse circuit 1 and the external pad 3 shown in FIG. 1. The LT-fuse detecting circuit 5 has an NMOS transistor (hereafter expressed as “TRN”) as a switching means. A test mode signal (TE) is inputted to the gate of the NMOS transistor (TRN) included in the LT-fuse detecting circuit 5.

In this arrangement, the test mode signal (TE) of a gate input becomes “H”-level in a test mode (i.e., LT-fuse detecting mode). In a preferred embodiment, a test mode (i.e., LT-fuse detecting mode) is started before a full-scale LT process is executed, and the H-level test mode signal (TE) is supplied to the gate of the TRN. Thereby, the LT fuse circuit 1 is electrically connected with the external pad 3. Therefore, it is possible to monitor a voltage or current by the external pad 3 and thereby, it is possible to confirm whether any trouble occurs in a fuse blow and success or failure of the fuse blow is determined.

It is noted here that a new external pad or a used output pad may be used as the external pad 3 in the embodiments 1 and 2.

In this embodiment, as a step of staring a test mode (i.e., LT-fuse detecting mode) is set before a full-scale LT process is executed, it is possible to efficiently determine the state of fuse blow when necessary.

Moreover, though a test mode is started before full-scale LT in this embodiment, the same advantage can be obtained when the test mode is started after full-scale LT is execued.

[Embodiment 3]

In the embodiment 3, the LT fuse circuit 1 of the embodiment 1 shown in FIG. 1 is provided for a TEG (Test Element Group) section. In this case, the TEG section provided with the LT-fuse circuit is located in a portion other than a chip portion, for example, a gap between chips such as a dicing portion.

By using the above configuration, it is possible to previously confirm in a LT process whether the energy quantity for fuse blow is normal. If the energy quantity is abnormal, it is possible to confirm that the energy quantity is abnormal before blowing an actual fuse, and thus prevent a blow error.

[Embodiment 4]

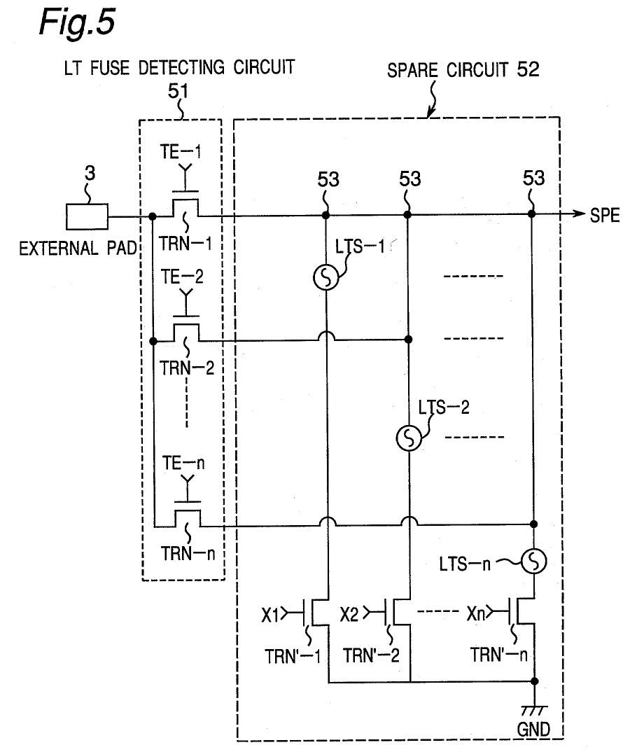

As shown in FIG. 5, in this embodiment 4, an LT-fuse detecting circuit 51 is connected between a conventional spare circuit 52 (or power-source voltage tuning circuit) and an external pad 3. The LT-fuse detecting circuit 51 has a configuration in which NMOS transistors TRN-1 to TRN-n (hereafter expressed as “TRN-i”) are arranged in parallel as a plurality of switching elements. Test mode signals TE-1 to TE-n (hereafter expressed as “TE-i”) are input to gates of the TRN-1 to TRN-n to turn on/off the transistors TRN-i.

The spare circuit 52 is constituted by arranging a plurality of LT fuses LTS-i (i=1-n) in parallel correspondingly to the TRN-i (i=1-n) in the LT-fuse detecting circuit 51 and each TRN-i of the LT-fuse detecting circuit 51 is electrically connected between a corresponding LT fuse LTS-i and the external pad 3. Moreover, the spare circuit 52 includes second NMOS transistors TRN′-i (i=1−n) between each LT fuse LTS-i and a ground GND. Each bit signal Xi (i=1−n) of input address is inputted to the gate of each of the second NMOS transistors TRN′-i. Thereby, even if there is a portion having no stress applied, a current can flow through an imperfectly-cut fuse portion, thereby providing a circuit configuration capable of blow-checking all cases.

In this arrangement, a test mode (i.e., LT-fuse detecting mode) is started before or after a full-scale LT process to check by the external pad 3 whether the fuse blow is normally performed by monitoring the current flowing between the external pad and the ground (GND).

For example, the operation of starting a test mode (LT-fuse detecting mode) before a full-scale LT process will be described below.

A test mode signal input to each gate of the TRN-i of the LT-fuse detecting circuit 51 becomes “H”-level in the test mode to electrically connect the external pad 3 (potential Vpad) with the node 53. In this case, the external pad 3 (potential Vpad) is electrically connected with the ground (GND) through each LT fuse LTS-i. Thereby, it is confirmed whether a fuse-blow error is present by monitoring a voltage or current by the external pad 3.

In FIG. 5, a spare enable signal SPE-for activating the spare (redundant) circuit 52 is generated in the node 53 to remedy a defective cell or the like. The LT fuses LTS-i (i=1−n) are connected to the nodes 53 in parallel. When an input-address bit signal Xi coincides with a defective address, the spare enable signal SPE is set to logical high level (H) to cut a corresponding LT fuse by blowing with a laser beam.

The fuse-cut state determining operation of this embodiment will be described below. The test mode signals TE-i (i=1−n) input to the gates of the TRN-i of the LT-fuse detecting circuit 51 are set to L level other than the case of determining and remedying an imperfectly-cut fuse. When the test mode signals are set to L level, the TRN-i is turned off and the external pad 3 is electrically disconnected from the determination node 53.

Then, an LT fuse corresponding to a defective address among the input addresses X1 to Xn is cut through laser blow.

A case in which an imperfectly-cut fuse is present will be described below by referring to FIGS. 2, 3 and 5.

When an LT fuse is perfectly cut as shown in FIG. 2B, the determination node 53 is completely disconnected from a corresponding second NMOS transistor TRN′-i. Therefore, when the input address Xi coincides with a defective address, the potential of the determination node 53 (that is, potential of spare enable SPE) is kept H-level. However, when an imperfect-cut fuse is present as shown in FIG. 2C, the potential of the node 53 slowly changes from L level (GND) to H level because the node 53 is connected with a corresponding second NMOS transistor TRN′-i through the uncut connective portion 21.

When the defective address signal Xi is inputted to the gate of the second NMOS transistor TRN′-i, the voltage Vpad is applied to the external pad 3, and then the test signal TE-i is raised from L level to H level. As a result, the external pad 3 is electrically connected with the determination node 53.

When a fuse is perfectly cut as shown in FIG. 2B, the node 53 is completely insulated from the corresponding second NMOS transistor TRN′-i and there flows no current between the external pad 3 and the ground potential GND (Vss). Moreover, when the corresponding second NMOS transistor TRN′-i is turned off (electrically disconnected state), no current flows between the external pad 3 and the ground potential GND similarly to the case of FIG. 2B.

When there is an imperfectly-cut fuse as shown in FIG. 2C, the current Ic flows between the external pad 3 and the ground potential GND as shown in FIG. 3 because the node 53 is electrically connected with the corresponding second NMOS transistor TRN′-i through the uncut corrective portion 21. Therefore, it is possible to determine the presence or absence of an imperfectly-cut fuse by monitoring the current Ic flowing between the external pad 3 and the ground potential GND.

It is possible to determine that a fuse is perfectly cut when the current Ic is equal to 0 in FIG. 3 and that there is an imperfectly-cut fuse when the current Ic is larger than 0. It is preferable that the threshold Iref is set for determination of the current Ic similarly to the case of the embodiment 1.

Since the same is true for the case of starting the test mode (LT-fuse detecting mode) after execution of the full-scale LT process, the description thereof in the above case is omitted here.

When imperfect cutting of a fuse is determined in the previous check of a fuse-cut state determination, an action such as optimization of the energy quantity of a laser beam or re-control of the shift of a laser-beam applying direction is taken so as to securely perform LT-fuse cutting.

In this embodiment, the LT-fuse detecting circuit 5 shown in FIG. 4 is provided with an NMOS transistor as a switching means. However, it is also possible to use such as a PMOS transistor or logic device.

Thus, in this embodiment, the LT-fuse detecting circuit 51 is connected between each fuse circuit of a spare circuit 52 and an external pad 3 to set a fuse portion to be checked after the LT-fuse detecting mode is started.

According to the above configuration, an advantage is obtained that it is possible to blow-check a fuse actually blown, and if the fuse is not accurately blown, the fuse is accurately blown again or blown by changing energy quantities for fuse blow.

[Embodiment 5]

In this embodiment 5, the LT-fuse detecting mode is started after execution of a full-scale LT process by using the same circuit arrangement as the embodiment 4 shown in FIG. 5. Then, a fuse actually blown is blow-checked, and if the fuse is not accurately blown after the blow-checking, an overvoltage is applied from the external pad 3 in order to blow the fuse again. Thus, an imperfectly-cut fuse after LT blow is securely blown. In this case, the overvoltage is higher than the external Vcc voltage. For example, when the external Vcc is 3 V, an overvoltage of Vcc=6V is applied to the spare circuit 52 from the external pad 3.

By this arrangement, after blow-checking a fuse actually blown, if the fuse is not accurately blown, it is possible to securely blow an imperfectly-cut fuse through LT blow by applying an overvoltage from the external pad 3.

[Embodiment 6]

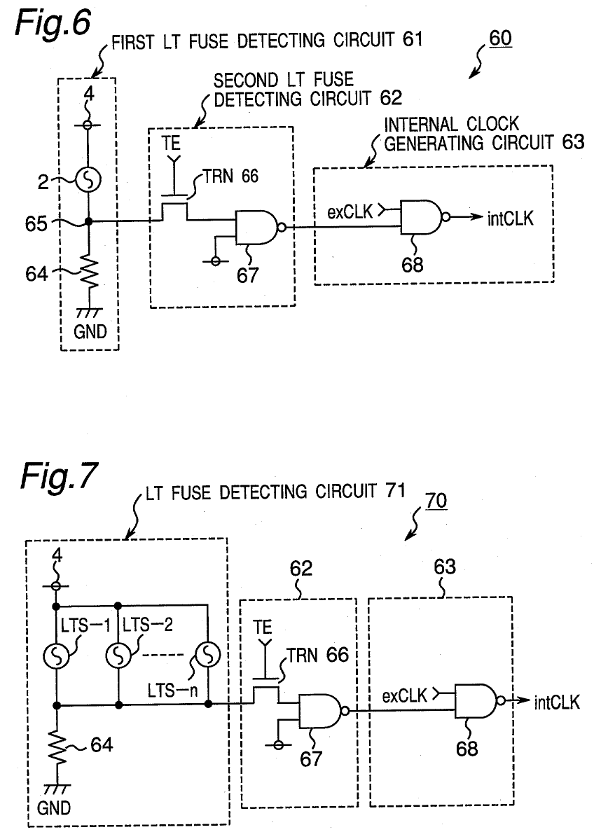

In this embodiment, as shown in FIG. 6, an LT-fuse detecting circuit 60 includes a fist LT-fuse detecting circuit 61, a second LT-fuse detecting circuit 62, and an internal-clock generating circuit 63. The first LT-fuse detecting circuit 61 has a configuration in which a fuse 2 and a resistor 64 are connected via a node 65 between a node 4 and a ground GND in series.

The second LT-fuse detecting circuit 62 includes an NMOS transistor TRN 66 as a switching device and a NAND gate 67 and the NMOS transistor TRN 66 is connected between the node 65 of the first LT-fuse detecting circuit 61 and the NAND gate 67.

The internal-clock generating circuit 63 includes a NAND gate 68, an external clock is inputted to one input terminal of the NAND gate 68, and an output of the NAND gate 67 of the second LT-fuse detecting circuit 62 is inputted to the other input terminal thereof. Operations of the above configuration will be described below.

When a blow error of an LT fuse is detected in the first LT-fuse detecting circuit 61, the LT-fuse detecting mode is started and a test mode signal TE inputted to the gate of the TRN 66 becomes H-level. Thereby, the H level signal is inputted to the internal-clock generating circuit 63 from the second LT-fuse detecting circuit 62. As a result, the NAND gate 68 does not accept an external clock exCLK in the internal-clock generating circuit 63 but it fixes a generated internal clock signal IntCLK to H level and detects a blow error of an LT fuse without performing internal operations.

According to the above configuration, it is possible to detect a blow error of an LT fuse by preventing an internal operation from functioning.

[Embodiment 7]

FIG. 7 shows a LT-fuse detecting circuit 70 of this embodiment. In the LT-fuse detecting circuit 70, a first LT-fuse detecting circuit 71 is constituted so that the fuse section of the first LT-fuse detecting circuit 61 shown in FIG. 6 of the embodiment 6 has a configuration in which a plurality of fuses LTS-i (i=1−n) are connected each other in parallel as shown in FIG. 7. That is, when a blow error of an LT fuse is present, the LT-fuse detecting mode is started by the same manner as in the case of the embodiment 6 and H level signal is inputted to the internal-clock generating circuit 63 from the second LT-fuse detecting circuit 62.

In this operation, the NAND gate 68 does not accept an external clock exCLK in the internal-clock generating circuit 63 but it fixes an internal clock intCLK to H level and detects a blow error of an LT fuse by preventing internal operations from being performed. By using the above configuration, it is possible to detect blow errors when continuously blowing fuses.

As described above, according to the present invention, it is possible to previously confirm whether the energy quantity for fuse blow is normal in a LT process. If the energy quantity is abnormal, it is possible to optimize the energy quantity for fuse blow before performing a fuse blow in a full-scale LT process, thus preventing a blow error.

Moreover, by setting a step of starting a test mode before or after a full-scale LT process, it is possible to efficiently determine success or failure of the fuse blow state according to necessity.

Furthermore, an advantage is obtained that it is possible to blow-check a fuse actually blown, and if the fuse is not accurately blown, it is possible to accurately blow the fuse by blowing the fuse again or by changing energy quantities for fuse blow and thereby blowing the fuse again.

Although the present invention has been described in connection with the preferred embodiments thereof with reference to the accompanying drawings, it is to be noted that various changes and modifications will be apparent to those skilled in the art. Such changes and modifications are to be understood as included within the scope of the present invention as defined by the appended claims, unless they depart therefrom.

What is claimed is:

1. A laser-trimming fuse detecting circuit for determining a blown state of a laser-trimming fuse of a semiconductor integrated circuit, comprising:
a laser-trimming fuse circuit provided in a chip section of the semiconductor integrated circuit and having a laser trimming fuse;
an external pad; and
a node having a predetermined potential difference from the external pad,
wherein the external pad is connected with the node in series through the laser-trimming fuse to determine a blown state of the laser-trimming fuse through the external pad.

2. The laser-trimming fuse detecting circuit according to claim 1, wherein said laser trimming fuse of said laser-trimming fuse circuit is preliminarily blown before executing a full-scale laser trimming process.

3. The laser-trimming fuse detecting circuit according to claim 1, further comprising a laser-trimming fuse detecting circuit which is connected between said laser-trimming fuse circuit and said external pad, wherein the laser-trimming fuse detecting circuit has switching means to be turned on/off in accordance with input of a test mode signal, and said laser-trimming fuse circuit is electrically connected with said external pad when the switching means is turned on.

4. The laser-trimming fuse detecting circuit according to claim 1, wherein said laser-trimming fuse circuit is located in a TEG section of said semiconductor integrated circuit.

5. A laser-trimming fuse detecting circuit for determining a blown state of a laser trimming fuse of a semiconductor integrated circuit, comprising:
a spare circuit;
an external pad; and
a laser-trimming fuse detecting circuit connected between the spare circuit and the external pad,
wherein the laser-trimming fuse detecting circuit is provided with a plurality of switching elements which are connected in parallel with each other, and
wherein the spare circuit is provided with a plurality of laser trimming fuses which are connected in parallel with each other correspondingly to the switching elements, respectively, and
each of the switching elements is connected between the corresponding laser trimming fuse and the external pad.

6. The laser-trimming fuse detecting circuit according to claim 5, wherein each of said switching elements is turned on/off in accordance with input of a test mode signal.

7. The laser-trimming fuse detecting circuit according to claim 5, wherein said spare circuit includes a plurality of second switching elements between the laser trimming fuses and a ground, and each of said second switching elements receives an input address signal Xi as a gate signal thereof.

8. The laser-trimming fuse detecting circuit according to claim 5, wherein a laser-trimming fuse detecting mode is started after executing a laser trimming process and a fuse actually blown is subject to blow-check in the laser-trimming fuse detecting mode, and when it is judged that the blow-checked fuse is not accurately blown, an overvoltage is applied to said spare circuit from said external pad to thereby perfectly blow the fuse again.

9. A laser-trimming fuse detecting circuit for determining a blown state of a laser trimming fuse of a semiconductor integrated circuit, comprising:
a first laser-trimming fuse detecting circuit in which a fuse is connected between a node and a ground in series;
a second laser-trimming fuse detecting circuit including a switching element and a first logic circuit; and
an internal-clock generating circuit which includes a second logic circuit and one input terminal of said second logic circuit receives an output of said second laser-trimming fuse detecting circuit to generate an internal operation clock;
thereby detecting a blown state of a laser-trimming fuse with an internal operation of the internal-clock generating circuit kept disable.

10. The laser-trimming fuse detecting circuit according to claim 9, wherein said first laser-trimming fuse detecting circuit includes a plurality of fuses arranged in parallel.

11. A laser-trimming fuse detecting method for determining a blown state of a laser trimming fuse in a laser trimming process of a semiconductor integrated circuit, comprising steps of:
blow-cutting a laser trimming fuse connected between an external pad and a node of a chip section of the semiconductor integrated circuit;
applying a predetermined potential difference between the external pad and the node; and
monitoring a current flowing through the external pad,
wherein a blown state of the laser-trimming fuse is determined through the external pad.

12. The laser-trimming fuse detecting method according to claim 11, wherein the laser trimming fuse is preliminarily blown before executing a full-scale laser trimming process.

13. The laser-trimming fuse detecting method according to claim 11, wherein the laser trimming process comprises steps of: starting a test mode for detecting an laser-trimming fuse; electrically connecting the laser trimming fuse with the external pad; and determining success or failure of the fuse blow state by monitoring a current flowing through the external pad.

14. A laser-trimming fuse detecting method for determining a blown state of a laser-trimming fuse of a spare circuit from an external pad in a semiconductor integrated circuit, comprising:
blow-cutting a laser-trimming fuse corresponding to a defective address among input addresses;
starting a test mode for detecting a blown state of a laser-trimming fuse in a laser trimming process; and
electrically connecting the external pad with the node; and
determining a blown state of the laser-trimming fuse by the external pad by monitoring the current flowing through the external pad.

15. The laser-trimming fuse detecting method according to claim 14, wherein the test mode is started after executing a laser trimming process and a fuse actually blown is subject to blow-check in the test mode, and when it is judged that the blow-checked fuse is not accurately blown, an overvoltage is applied to the spare circuit from the external pad to thereby perfectly blow the fuse again.
